(19) United States
(12) Patent Application Publication
(10) Pub. No.: US 2017/0221939 A1
(43) Pub. Date: Aug. 3, 2017

(54) FUNCTIONAL ELEMENT AND ELECTRONIC APPARATUS

(71) Applicant: SONY CORPORATION, Tokyo (JP)

(72) Inventors: Izuho HATADA, Kanagawa (JP); Shinya YAMAKAWA, Kanagawa (JP); Atsushi SUZUKI, Kanagawa (JP)

(73) Assignee: SONY CORPORATION, Tokyo (JP)

(21) Appl. No.: 15/329,666

(22) PCT Filed: Jul. 23, 2015
(86) PCT No.: PCT/JP2015/070953

§ 371 Date: Jan. 27, 2017

(30) Foreign Application Priority Data
Aug. 6, 2014 (JP) 2014-160216

(51) Int. Cl. H01L 27/146; G01T 1/20; H01L 31/0224; H01L 31/117; H01L 31/0352

(52) U.S. Cl. CPC H01L 27/1461; H01L 27/14607; H01L 31/117; H01L 27/14636; H01L 31/035272; H01L 27/14663; H01L 27/14629; H01L 27/14685; H01L 31/022408; G01T 1/2018

(57) ABSTRACT

A functional element of an embodiment of the technology includes: a first region and a ring-like second region on a top surface of a semiconductor layer having an end surface, the second region surrounding the first region in a space between the first region and the end surface. The functional element of the technology includes a first functional section in the second region, the first functional section allowing for induction of carriers arising on the end surface to outside.

### TECHNICAL FIELD

The technology relates to a functional element having a semiconductor layer, and to an electronic apparatus that includes such a functional element.

### BACKGROUND ART

In a semiconductor, collapse in crystal structure may exist in any way on an end surface that is formed by cutoff. In a photodiode, it has been known that a dark current may occur due to such collapse in the crystal structure. The dark current contributes to an electrical noise for a signal current obtained by the photodiode, and therefore it is necessary to reduce the dark current itself, or to reduce an influence that the dark current exerts on the signal current. To solve such an issue, an approach has been recently known that reduces an influence that the dark current exerts on the signal current by keeping a light receiving region away from an end surface. Further, for example, PTLs 1, 2, and 3 have proposed to reduce the dark current itself by providing a coating layer on the end surface, or by providing an impurity layer to reach a semiconductor substrate from a surface of a semiconductor layer in a scribing line.

### CITATION LIST

### Patent Literature

[PTL 1] Japanese Unexamined Patent Application Publication No. 2010-239005
[PTL 2] Japanese Unexamined Patent Application Publication No. 2008-177485
[PTL 3] Japanese Unexamined Patent Application Publication No. H07-142586

### SUMMARY OF INVENTION

However, in a case where a light receiving region is reduced in size to keep the light receiving region away from an end surface, the amount of light received decreases by reduction in size of the light receiving region, and therefore such a case has been disadvantageous in that an S/N ratio may deteriorate. Alternatively, to provide a coating layer on the end surface, or to provide an impurity layer to run through a semiconductor layer, it is necessary to add dedicated processes for such purposes. This has resulted in an issue of an increase in manufacturing costs.

It is to be noted that, even in a variety of functional elements that each include a semiconductor layer having an end surface, an issue of deterioration in S/N ratio or an increase in manufacturing costs may arise due to the dark current occurring in the end surface.

Accordingly, it is desirable to provide a functional element that makes it possible to reduce an influence that the dark current exerts on the signal current, while suppressing deterioration in the S/N ratio and an increase in manufacturing costs, and an electronic apparatus that includes such a functional element.

A functional element of an embodiment of the technology includes: a first region and a ring-like second region on a top surface of a semiconductor layer having an end surface, the second region surrounding the first region in a space between the first region and the end surface. The functional element of the technology includes a first functional section in the second region, the first functional section allowing for induction of carriers arising on the end surface to outside.

An electronic apparatus according to an embodiment of the technology includes the above-described functional element and a controller that controls the above-described functional element.

In the functional element and the electronic apparatus according to the respective embodiments of the technology, the first functional section that allows for induction of carriers arising on the end surface to outside is provided in the second region surrounding the first region in a space between the first region and the end surface. This allows the first functional section to draw a dark current arising on the end surface to the outside, and therefore it is possible to reduce an influence that the dark current arising on the end surface exerts on the first region even if the first region is provided in the vicinity of the end surface. Further, the first functional section may only serve as a current path for the dark current arising on the end surface, which eliminates necessity for providing the first functional section in large size, and eliminates necessity for providing a coating layer on the end surface, or providing an impurity layer that runs through the semiconductor layer.

According to the functional element and the electronic apparatus of the respective embodiments of the technology, the first functional section that allows for induction of carriers arising on the end surface to outside is provided in the second region surrounding the first region, and therefore it is possible to reduce an influence that the dark current arising on the end surface exerts on a signal current flowing through the first region, while suppressing deterioration in an S/N ratio and an increase in manufacturing costs. It is to be noted that effects of the technology are not necessarily limited to the effects described here, and may be one or more of effects described in the present description.

### BRIEF DESCRIPTION OF DRAWINGS

FIG. 1 is a diagram illustrating an example of a cross-sectional configuration of a radiation detector according to a first embodiment of the technology.

FIG. 2 is a diagram illustrating an example of a top-surface configuration of the radiation detector illustrated in FIG. 1.

FIG. 3 is a diagram illustrating an example of a bottom-surface configuration of a light receiving element illustrated in FIG. 1.

FIG. 4 is a diagram illustrating an example of a cross-sectional configuration of the light receiving element taken along a line A-A illustrated in FIG. 3.

FIG. 5 is a diagram illustrating an example of a cross-sectional configuration of the light receiving element taken along the line A-A illustrated in FIG. 3.

FIG. 6 is a diagram illustrating an example of a cross-sectional configuration of the light receiving element taken along the line A-A illustrated in FIG. 3.

FIG. 7 is a diagram illustrating an example of a cross-sectional configuration of the light receiving element taken along the line A-A illustrated in FIG. 3.

FIG. 8 is a chart representing an example of a procedure of manufacturing the radiation detector including the light receiving element illustrated in FIG. 3 to FIG. 7.

FIG. 9 is a diagram illustrating an example of a cross-sectional configuration of a light receiving element according to a comparative example.

FIG. 10 is a diagram illustrating an example of a cross-sectional configuration of a light receiving element according to a comparative example.

FIG. 11 is a diagram illustrating an example of dependency of a dark current on an outer cathode voltage that is derived by simulation.

FIG. 12 is a diagram illustrating an example of a simulation result in the light receiving element according to the comparative example illustrated in FIG. 10.

FIG. 13 is a diagram illustrating an example of a simulation result in the light receiving element illustrated in FIG. 9.

FIG. 14 is a diagram illustrating an example of a simulation result in the light receiving element illustrated in FIG. 9.

FIG. 15 is a diagram illustrating an example of a simulation result in the light receiving element illustrated in FIG. 4.

FIG. 16 is a diagram illustrating an example of a simulation result in the light receiving element illustrated in FIG. 4.

FIG. 17 is a diagram illustrating an example of a simulation result in the light receiving element illustrated in FIG. 7.

FIG. 18 is a diagram illustrating an example of a simulation result in the light receiving element illustrated in FIG. 7.

FIG. 19 is a diagram illustrating an example of dependency of a photocurrent on an outer cathode voltage that is derived by simulation.

FIG. 20 is a diagram illustrating a modification example of a bottom-surface configuration of the light receiving element illustrated in FIG. 3.

FIG. 21 is a diagram illustrating a modification example of a bottom-surface configuration of the light receiving element illustrated in FIG. 3.

FIG. 22 is a diagram illustrating a modification example of a bottom-surface configuration of the light receiving element illustrated in FIG. 3.

FIG. 23 is a diagram illustrating a modification example of a bottom-surface configuration of the light receiving element illustrated in FIG. 3.

FIG. 24 is a diagram illustrating a modification example of a bottom-surface configuration of the light receiving element illustrated in FIG. 3.

FIG. 25 is a diagram illustrating an example of a cross-sectional configuration of a radiation detector according to a second embodiment of the technology.

FIG. 26 is a diagram illustrating an example of a top-surface configuration of the radiation detector illustrated in FIG. 25.

FIG. 27 is a diagram illustrating an example of a bottom-surface configuration of the radiation detector (circuit substrate) illustrated in FIG. 25.

FIG. 28 is a diagram illustrating an example of a cross-sectional configuration of the circuit substrate taken along a line A-A illustrated in FIG. 27.

FIG. 29 is a chart representing an example of a procedure of manufacturing the radiation detector illustrated in FIG. 25.

FIG. 30 is a diagram illustrating an example of a simplified configuration of an imaging device according to a third embodiment of the technology.

FIG. 31 is a diagram illustrating an example of a circuit configuration of an imaging section illustrated in FIG. 30.

FIG. 32 is a diagram illustrating an example of a simplified configuration of an imaging display system according to a fourth embodiment of the technology.

### MODES FOR CARRYING OUT THE INVENTION

Hereinafter, some embodiments of the disclosure will be described in detail with reference to the drawings. It is to be noted that description will be given in the following order.

### 1. First Embodiment (Radiation Detector)

An example where a dark current induction section is provided at an end edge on each pixel

### 2. Modification Examples of First Embodiment (Radiation Detector)

Variations of in-plane layout of each impurity region

### 3. Second Embodiment (Radiation Detector)

An example where a dark current induction section is provided at an end edge of a circuit substrate

### 4. Modification Example Common to Each of Embodiments (Radiation Detector)

An example where a scintillator layer is omitted

### 5. Third Embodiment (Imaging Device)

An example where the radiation detector according to each of the above-described embodiments is used as an imaging section of an imaging device

### 6. Fourth Embodiment (Imaging System)

An example where the above-described imaging device is built into an imaging system

### 7. Modification Example of Fourth Embodiment (Imaging System)

An example where a molding apparatus is further provided

### 1. First Embodiment

### [Configuration]

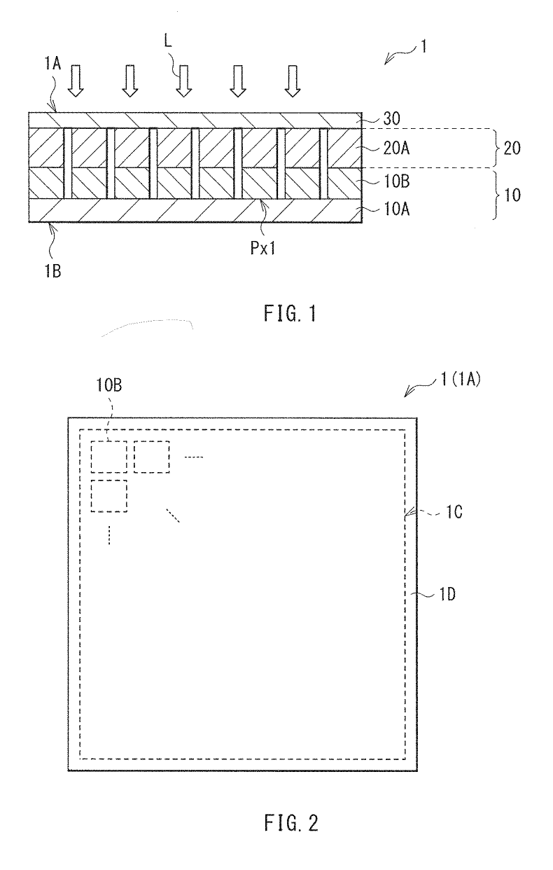

First, a description will be provided on a radiation detector 1 according to a first embodiment of the technology. FIG. 1 illustrates an example of a cross-sectional configuration of the radiation detector 1 according to the present embodiment. FIG. 2 illustrates an example of a configuration of a top surface 1A of the radiation detector 1 illustrated in FIG. 1. The radiation detector 1 detects radiation such as α ray, β ray, γ ray, or X-ray, and is a radiation detector of an indirect conversion method. The indirect conversion method refers to a method in which a radiation ray is converted into an optical signal, and thereafter the resulting optical signal is converted into an electrical signal. The radiation detector 1 may include, for example, a circuit substrate 10, a scintillator layer 20, and a reflective plate 30.

(Circuit Substrate 10)

The circuit substrate 10 converts an optical signal into an electrical signal. The circuit substrate 10 includes a wiring substrate 10A, and a plurality of light receiving elements 10B. The light receiving element 10B corresponds to a specific example of a “functional element” in the technology. The wiring substrate 10A is disposed on a bottom surface 1B side of the radiation detector 1, and each of the light receiving elements 10B is disposed on the scintillator layer 20 side. The wiring substrate 10A may have, for example, a support substrate, a driving circuit that is provided on the support substrate, and a variety of wiring for coupling of the driving circuit and the light receiving elements 10B to external circuits. The support substrate may be configured of, for example, a semiconductor substrate or a glass substrate. The driving circuit may have, for example, a plurality of transistors that perform on/off control of the light receiving elements 10B on the basis of a control signal from an external circuit. Each of the transistors may be configured of, for example, a field-effect thin-film transistor (TFT). The plurality of transistors are provided one by one for the light receiving elements 10B, and a pair of the light receiving element 10B and the transistor configures an imaging pixel Px1. The wiring substrate 10A may be configured to include, for example, a conversion circuit that converts a photocurrent to be outputted from the light receiving element 10B into a voltage signal, an amplifier circuit that amplifies the voltage signal to be outputted from the conversion circuit, and an A/D conversion circuit that converts an analog signal to be outputted from the amplifier into a digital signal. One or more of the conversion circuit, the amplifier circuit, and the A/D conversion circuit may be provided in the driving circuit.

The light receiving element 10B is configured to include a photoelectric converter 10E (to be hereinafter described) that generates a signal charge (photocurrent) of a charge amount corresponding to a amount of light (incident light) coming into a top surface of the light receiving element 10B from the scintillator layer 20 side to accumulate such a signal charge internally. The photoelectric converter 10E corresponds to a specific example of a “second functional section” in the technology. The photoelectric converter 10E may be configured of, for example, a PN (Positive Negative) photodiode or a PIN (Positive Intrinsic Negative) photodiode. The photoelectric converter 10E will be later described in detail.

The plurality of light receiving elements 10B are disposed at positions facing a region (pixel region 1C) excluding an end edge (frame region 1D) on the top surface 1A of the radiation detector 1. The plurality of light receiving elements 10B are mounted on the common wiring substrate 10A. The plurality of light receiving elements 10B may be disposed two-dimensionally on the wiring substrate 10A, for example. The light receiving element 10B may be transcribed on the wiring substrate 10A utilizing a transcription technique, for example. The plurality of light receiving elements 10B are disposed away from one another in plane. Therefore, the top surface of the light receiving element 10B is surrounded by a void formed between adjacent two of the light receiving elements 10B. A width of the void may be, for example, equal to or smaller than a lateral width of the light receiving element 10B.

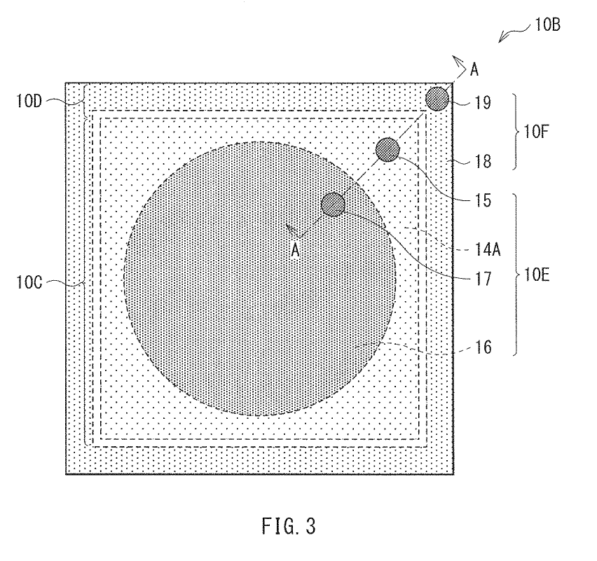

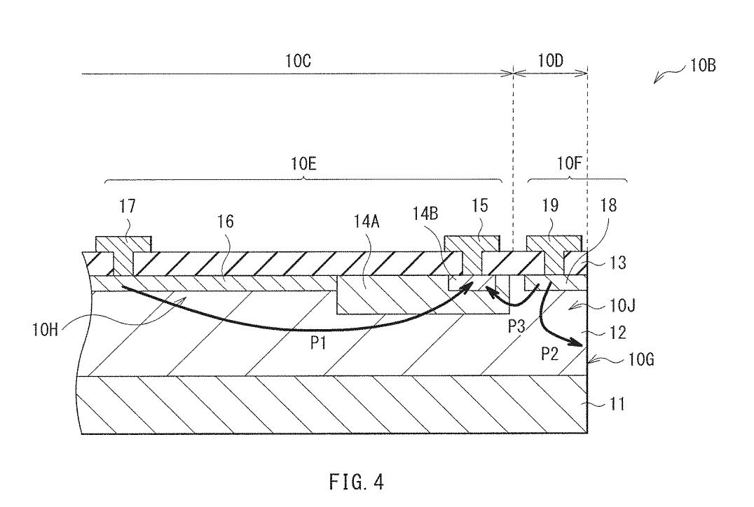

FIG. 3 illustrates an example of a bottom-surface configuration of the light receiving element 10B. FIG. 4 illustrates an example of a cross-sectional configuration of the light receiving element 10B taken along a line A-A illustrated in FIG. 3. FIG. 4 illustrates a cross-sectional surface of the light receiving element 10B upside down. Hereinafter, in explaining each component element inside the light receiving element 10B, an upper side of FIG. 4 is referred to as a top, and a lower side of FIG. 4 is referred to as a bottom. The light receiving element 10B may be, for example, a chip of a submillimeter size. It is to be noted that the light receiving element 10B may have a size greater than the submillimeter size. The light receiving element 10B has an end surface 10G that is formed by being cut with use of dicing, dry etching, or any other method. The end surface 10G corresponds to a specific example of an “end surface” in the technology. The light receiving element 10B may take a cuboid shape, for example. For the purpose of protecting the light receiving element 10B or any other purpose, a protective film may be provided on the end surface 10G of the light receiving element 10B.

The light receiving element 10B has a p-type substrate 11, and a p-type semiconductor layer 12 and an insulating layer 13 that are provided on the p-type substrate 11. The p-type semiconductor layer 12 corresponds to a specific example of a “semiconductor layer” in the technology. The p-type semiconductor layer 12 and the insulating layer 13 are configured to be stacked in this order on the p-type substrate 11. The p-type semiconductor layer 12 is exposed on the end surface 10G of the light receiving element 10B. In other words, the p-type semiconductor layer 12 has the end surface 10G. The p-type substrate 11 may be, for example, a bulk silicon crystal substrate containing a p-type impurity with a high concentration of about 1×10¹⁷ cm⁻³. The p-type semiconductor layer 12 may be, for example, a p-type epitaxial silicon layer with a low concentration of about 1×10¹⁵ cm⁻³. Examples of the p-type impurity may include boron (B). The insulating layer 13 is formed by thermally oxidizing a surface of the bulk silicon crystal substrate.

The light receiving element 10B has, on the top surface of the p-type semiconductor layer 12, an inner region 10C, and a ring-like outer region 10D surrounding the inner region 10C in a space between the inner region 10C and the end surface 10G. The inner region 10C corresponds to a specific example of a “first region” in the technology. The outer region 10D corresponds to a specific example of a “second region” in the technology. The light receiving element 10B has a p-type well 14A in the inner region 10C, and has a p-type region 14B on a portion of the top surface of the p-type well 14A. The p-type region 14B corresponds to a specific example of a “third semiconductor region” in the technology. The p-type region 14B is intended to lower a contact resistance between an anode electrode 15 to be later described and the p-type well 14A, and has higher p-type impurity concentration than p-type impurity concentration of the p-type semiconductor layer 12 and the p-type well 14A. The p-type well 14A is provided on an outer edge of the inner region 10C in a circular pattern. The p-type well 14A is formed by diffusing the p-type impurity with respect to the p-type semiconductor layer 12 from the top surface of the p-type semiconductor layer 12. The p-type region 14B is formed by diffusing the p-type impurity in high concentration with respect to the p-type well 14A from the top surface of the p-type well 14A.

The light receiving element 10B has a conductive n-type region 16 that is different from the p-type semiconductor layer 12 in a region surrounded by the p-type well 14A on the top surface of the inner region 10C. The n-type region 16 corresponds to a specific example of a “second semiconductor region” in the technology. An outer edge of the n-type region 16 may be in contact with an inner edge of the p-type well 14A, for example. The n-type region 16 may be configured of, for example, a semiconductor with an n-type impurity concentration of about 1×10¹⁹ cm⁻³. Examples of the n-type impurity may include antimony (Sb) and arsenic (As). The n-type region 16 is formed by diffusing the n-type impurity in high concentration with respect to the p-type semiconductor layer 12 from the top surface of the p-type semiconductor layer 12. A p-n junction (junction region 10H) is provided at a boundary between the n-type region 16 and the p-type semiconductor layer 12 and at a boundary between the n-type region 16 and the p-type well 14A. The p-n junction (junction region 10H) corresponds to a specific example of a “p-n junction of the second functional section” in the technology. The light receiving element 10B has an anode electrode 15 that is electrically coupled to the p-type region 14B via an opening of the insulating layer 13. The anode electrode 15 corresponds to a specific example of a “third electrode” in the technology. Further, the light receiving element 10B has an inner cathode electrode 17 that is electrically coupled to the n-type region 16 via another opening of the insulating layer 13. The inner cathode electrode 17 corresponds to a specific example of a “second electrode” in the technology. The anode electrode 15 and the inner cathode electrode 17 may be made of, for example, a metallic material such as AlCu. The photoelectric converter 10E is configured of the p-type well 14A, the p-type region 14B, the n-type region 16, the junction region 10H, the anode electrode 15, and the inner cathode electrode 17. The photoelectric converter 10E serves as a current path P1 in the inner region C, and controls movement of carriers in the inner region C. It is to be noted that a direction of an arrow of the current path P1 indicates a current flow direction in FIG. 4. In FIG. 4, directions of arrows of current paths P2 and P3 also indicate current flow directions.

Further, the light receiving element 10B has an n-type region 18 in the outer region 10D. The n-type region 18 corresponds to a specific example of a “first semiconductor region” in the technology. The n-type region 18, the p-type region 14B, and the n-type region 16 are disposed in this order from the end surface 10G side. The n-type region 18 is not directly in contact with the p-type well 14A, and the n-type region 18 and the p-type well 14A are disposed with a predetermined space in between. The n-type region 18 is provided to be in contact with the end surface 10G. The n-type region 18 may be configured of, for example, a semiconductor with an n-type impurity concentration in the range of about 1×10¹⁸ cm⁻³ to about 1×10¹⁹ cm⁻³. The n-type region 18 is formed by diffusing the n-type impurity in high concentration with respect to the p-type semiconductor layer 12 from the top surface of the p-type semiconductor layer 12. A p-n junction (junction region 10J) is provided at a boundary between the n-type region 18 and the p-type semiconductor layer 12. The p-n junction (junction region 10J) corresponds to a specific example of a “p-n junction of the first functional section” in the technology. The light receiving element 10B has an outer cathode electrode 19 that is electrically coupled to the n-type region 18 via the opening of the insulating layer 13. The outer cathode electrode 19 corresponds to a specific example of a “first electrode” in the technology. The outer cathode electrode 19 may be made of, for example, a metallic material such as AlCu. A dark current induction section 10F that makes it possible to induce carriers arising on the end surface 10G to the outside is configured of the n-type region 18, a portion directly below the n-type region 18 of the junction region 10J, and the outer cathode electrode 19. The dark current induction section 10F corresponds to a specific example of a “first functional section” in the technology. The dark current induction section 10F serves as the current path P2 in the outer region 10D.

As described above, the end surface 10G is formed by being cut with use of dicing, dry etching, or any other method. Therefore, collapse in crystal structure may exist in any way on the end surface 10G, and carriers (that is, the dark current) are likely to occur due to such collapse in the crystal structure. The dark current induction section 10F makes it possible to draw and induce carriers arising on the end surface 10G to the outside by applying a predetermined voltage to the outer cathode electrode 19. Here, the “predetermined voltage” refers to a voltage that enables promotion of induction of carriers arising on the end surface 10G to the outside. For example, when a ground voltage or a negative voltage is applied to the anode electrode 15, the “predetermined voltage” refers to a positive voltage.

It is to be noted that the current path P3 may be provided also in a portion between the n-type region 18 and the p-type well 14A in the junction region 10J. However, as described later, an influence of a current flowing through the current path P3 on the current path P1 is negligibly small. Therefore, an influence of the dark current induction section 10F on the photoelectric converter 10E is negligibly small.

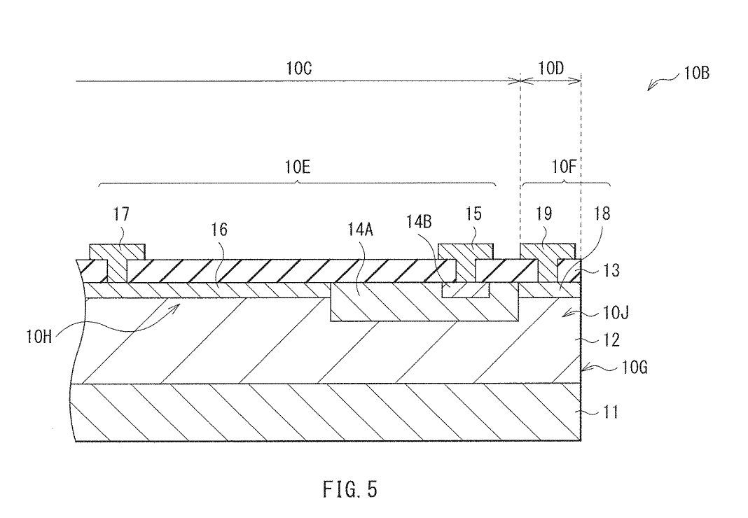

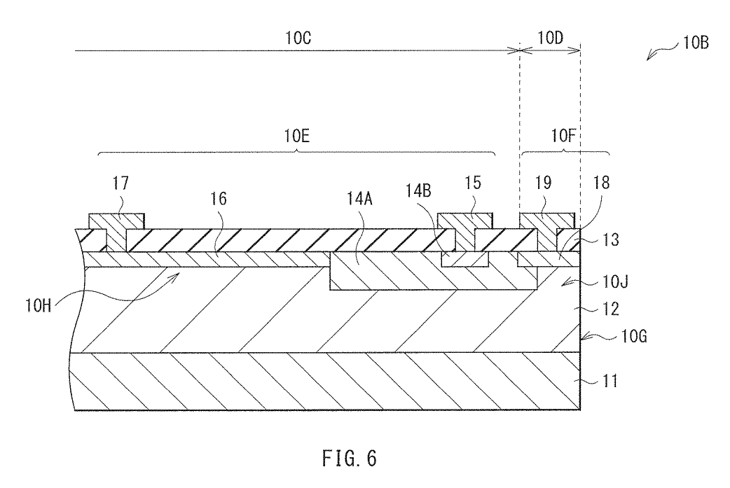

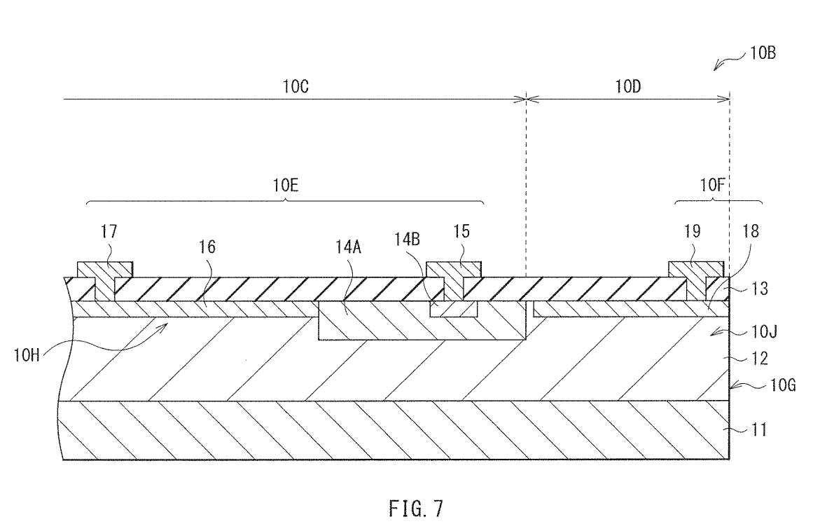

It is to be noted that an end of the p-type well 14A may be directly in contact with an end of the n-type region 18 as illustrated in FIG. 5. Further, as illustrated in FIG. 6, the end of the p-type well 14A may be also directly in contact with a portion on a lower surface of the n-type region 18 in addition to the end of the n-type region 18. Alternatively, as illustrated in FIG. 7, the n-type region 18 may be provided over a wide range. At this time, from the viewpoint of an S/N ratio, it may be preferable to widen the area of the n-type region 18 without changing the area of the n-type region 16.

(Scintillator Layer 20)

The scintillator layer 20 performs wavelength conversion of radiation L incoming into the top surface 1A into a sensitivity region of the photoelectric converter 10E, and specifically converts the radiation L incoming into the top surface 1A into light. The scintillator layer 20 is configured of a phosphor that converts radiation such as α ray, β ray, γ ray, or X-ray into visible light. Examples of such a phosphor may include a substance containing cesium iodide (CsI) with additive thallium (Tl) or sodium (Na), and a substance containing sodium iodide (NaI) with additive thallium (Tl). Alternatively, examples of the above-described phosphor may include a substance containing cesium bromide (CsBr) with additive europium (Eu), and a substance containing cesium fluorobromide (CsBrF) with additive europium (Eu).

The scintillator layer 20 is disposed on the upper side of the light receiving element 10B as illustrated in FIG. 1. For example, the scintillator layer 20 may be formed with use of the top surface of the light receiving element 10B as a crystal growing surface, and may be formed by performing film formation utilizing, for example, a vacuum evaporation technique. The scintillator layer 20 has a crystal interface extending in a thickness direction of the scintillator layer 20 in a region facing a space between adjacent two of the light receiving elements 10B. The crystal interface extends in the thickness direction of the scintillator layer 20 from the top surface of the light receiving element 10B, and segments the scintillator layer 20 one by one for each of the light receiving elements 10B. In other words, the scintillator layer 20 is configured of a plurality of scintillator sections 20A one of which is assigned to each of the light receiving elements 10B by the crystal interface.

(Reflective Plate 30)

The reflective plate 30 has a role of returning, to the side of the light receiving element 10B, light that is emitted toward a direction opposite to a direction from the scintillator layer 20 to the light receiving element 10B. The reflective plate 30 may be configured of a moisture-impermeable material that does not substantially allow moisture to pass through. In such a case, the reflective plate 30 allows for prevention of intervention of moisture into the scintillator layer 20. The reflective plate 30 may be made of, for example, thin sheet glass. The reflective plate 30 may be omitted. A reflective structure to be provided on the scintillator layer 20 may adopt any configuration other than the reflective plate 30 as described above, and may be configured of an aluminum evaporated film, for example.

[Manufacturing Method]

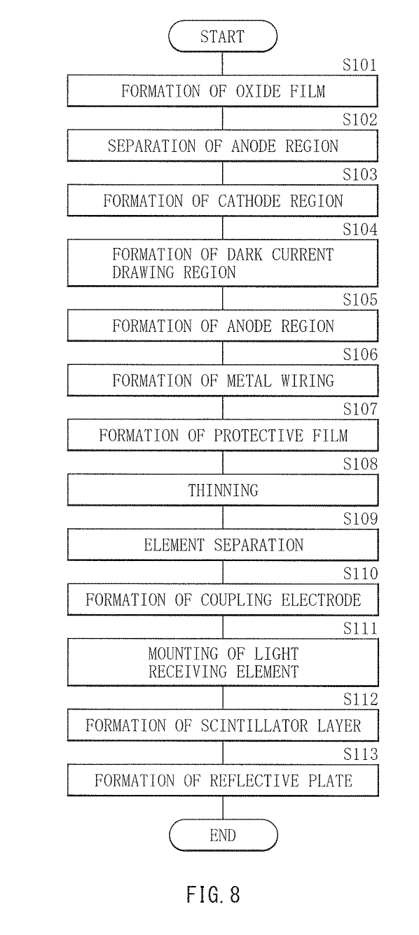

Next, a description will be provided on an example of a method of manufacturing the radiation detector 1. FIG. 8 represents an example of a procedure of manufacturing the radiation detector 1 that includes the circuit substrate 10 illustrated in FIG. 3 to FIG. 7. First, a semiconductor substrate provided with the p-type semiconductor layer 12 is prepared on the p-type substrate 11. Next, an oxide film is formed (step S101). Specifically, the insulating layer 13 that is configured of the oxide film is formed by thermally oxidizing the surface of the p-type semiconductor layer 12. Thereafter, an anode region is separated (step S102). Specifically, the plurality of ring-like p-type wells 14A are formed in a matrix pattern by performing p-type ion implantation. At this time, a concentration gradient may be provided for the p-type wells 14A by carrying out the p-type ion implantation a plurality of times.

Next, a cathode region is formed (step S103). Specifically, the n-type region 16 is formed in each region surrounded by the p-type well 14A by performing n-type ion implantation. Thereafter, a dark current drawing region is formed (step S104). Specifically, the lattice-like n-type region 18 that surrounds each of the p-type wells 14A is formed by carrying out the n-type ion implantation. At this time, when n-type impurity concentrations of the n-type regions 16 and 18 are made equal to each other, it is possible to form the n-type region 16 and the n-type region 18 collectively. Thereafter, the anode region is formed (step S105). Specifically, the p-type region 14B is formed by performing the p-type ion implantation on a portion of the top surface of each p-type well 14A.

Next, metal wiring is formed (step S106). Specifically, the plurality of anode electrodes 15, the plurality of inner cathode electrodes 17, and the plurality of outer cathode electrodes 19 are formed on the insulating layer 13. At this time, the anode electrodes 15 are assigned one by one to the p-type regions 14B; the inner cathode electrodes 17 are assigned one by one to the n-type regions 16: and the outer cathode electrodes 19 are assigned one by one to the p-type wells 14A. In such a manner, the plurality of photoelectric converters 10E and the lattice-like dark current induction section 10F that surrounds each of the photoelectric converters 10E are formed on the top surface of the p-type semiconductor layer 12. Thereafter, a protective film (not illustrated) that is made of a material such as SiO₂ or SiN is formed over the whole top surface as necessary (step S107).

Next, when the light receiving element 10B is used as a backside illumination type, the p-type substrate 11 is thinned (step S108). Thereafter, element separation is performed (step S109). Specifically, for example, after bonding a support substrate to the semiconductor substrate, dicing, dry etching, or any other method may be performed on a location where the dark current induction section 10F is formed on the semiconductor substrate to separate the semiconductor substrate for each of the photoelectric converters 10E. At this time, from the viewpoint of reducing a dark current arising from the end surface 10G to be formed by separation, it may be preferable to carry out the element separation with use of dry etching. In such a manner, the plurality of light receiving elements 10B having the end surfaces 10G are formed. Thereafter, a coupling electrode (not illustrated) for coupling of each of the light receiving elements 10B to the wiring substrate 10A is formed on each of the light receiving elements 10B, as necessary (step S110). After that, the plurality of light receiving elements 10B are mounted on the wiring substrate 10A using, for example, a transcription technique (step S111). In such a manner, the circuit substrate 10 as illustrated in FIG. 3 to FIG. 7 is manufactured.

Next, the scintillator layer 20 is formed with use of the top surface of each of the light receiving elements 10B as a crystal growing surface by performing film formation utilizing, for example, a vacuum evaporation technique (step S112). In forming the scintillator layer 20, in a region facing a space between adjacent two of the light receiving elements 10B, the crystal interface extending in the thickness direction of the scintillator layer 20 is formed, and the plurality of scintillator sections 20A that are assigned one by one for the light receiving elements 10B are formed by the crystal interface. Finally, the reflective plate 30 is formed on the scintillator layer 20 (step S113). With use of such a procedure, the radiation detector 1 is manufactured.

(Operation)

Next, a description will be provided on an example of operation of the radiation detector 1. When the radiation L comes into the top surface 1A of the radiation detector 1, the radiation L is converted into light on the scintillator layer 20. A reverse bias voltage is applied to the photoelectric converters 10E via the driving circuit and wiring inside the circuit substrate 10. When the converted light comes into the top surface of the light receiving element 10B, the photoelectric converter 10E generates a signal charge (photocurrent) of an amount corresponding to (proportional to) the amount of the incident light. The signal charge (photocurrent) that is generated in the photoelectric converter 10E is drawn by the driving circuit and wiring inside the circuit substrate 10 via the current path P1.

Meanwhile, on the end surface 10G of the light receiving element 10B, carriers may occur due to collapse in the crystal structure on the end surface 10G irrespective of the presence or absence of light incidence. A reverse bias voltage is applied to the dark current induction section 10F via the driving circuit and wiring inside the circuit substrate 10. The reverse bias voltage may be applied to the dark current induction section 10F at all times or intermittently. The carriers arising on the end surface 10G are drawn by the driving circuit and wiring inside the circuit substrate 10 via the current path P2.

[Simulation]

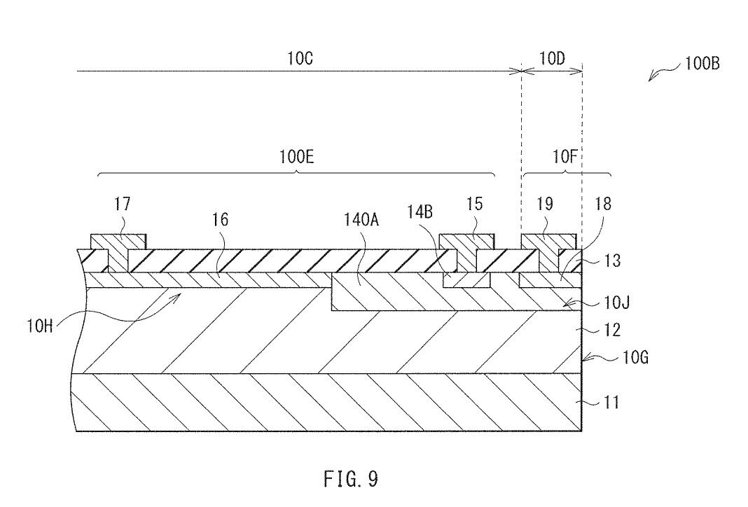

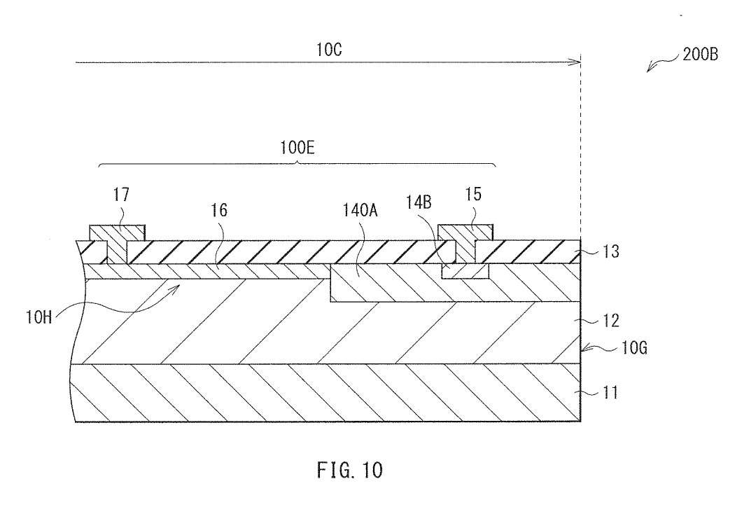

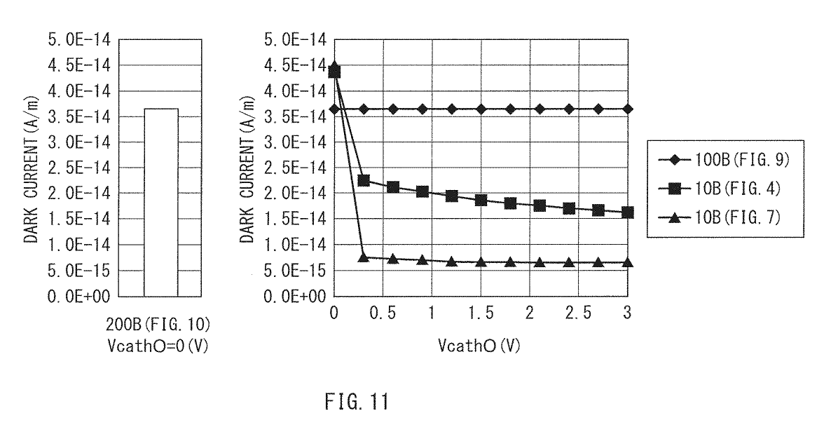

Next, a description will be provided on a simulation result in the light receiving element 10B. FIG. 9 illustrates an example of a cross-sectional configuration of a light receiving element 100B according to a comparative example. In the light receiving element 100B, the n-type region 18 is covered with the p-type well 140A, and is not in contact with the p-type semiconductor layer 12. FIG. 10 illustrates an example of a cross-sectional configuration of a light receiving element 200B according to a comparative example. In the light receiving element 200B, the dark current induction section 10F is not present, and the p-type well 140A extends as far as the end surface 10G. FIG. 11 illustrates an example of the dependency of a dark current on an outer cathode voltage that is derived by the simulation. A left-hand graph in FIG. 11 illustrates an example of a magnitude of a dark current arising in the light receiving element 200B. A right-hand graph in FIG. 11 illustrates an example of magnitudes of dark currents arising in the light receiving element 100B, and the light receiving element 10B illustrated in FIG. 4 and FIG. 7. The right-hand graph in FIG. 11 represents a result obtained when an inner cathode voltage VcathI is set to 0.6 V, and an anode voltage is set to a ground.

FIG. 11 indicates that when the n-type region 18 is covered with the p-type well 140A (FIG. 9), a magnitude of the dark current remains almost the same in comparison with a magnitude of the dark current when the dark current induction section 10F is not present. For this reason, it is found that the dark current induction section 10F functions by ensuring that at least a portion of the n-type region 18 is in contact with the p-type semiconductor layer 12. Further, it is seen from FIG. 11 that the dark current induction section 10F functions even if the area of the n-type region 18 is small, and the function of the dark current induction section 10F is more enhanced with an increase in the area of the n-type region 18. Moreover, FIG. 11 shows that the dark current induction section 10F functions sufficiently only by setting an outer cathode voltage VcathO to 0.3 V when the inner cathode voltage VcathI is set to 0.6 V, and the anode voltage is set to a ground.

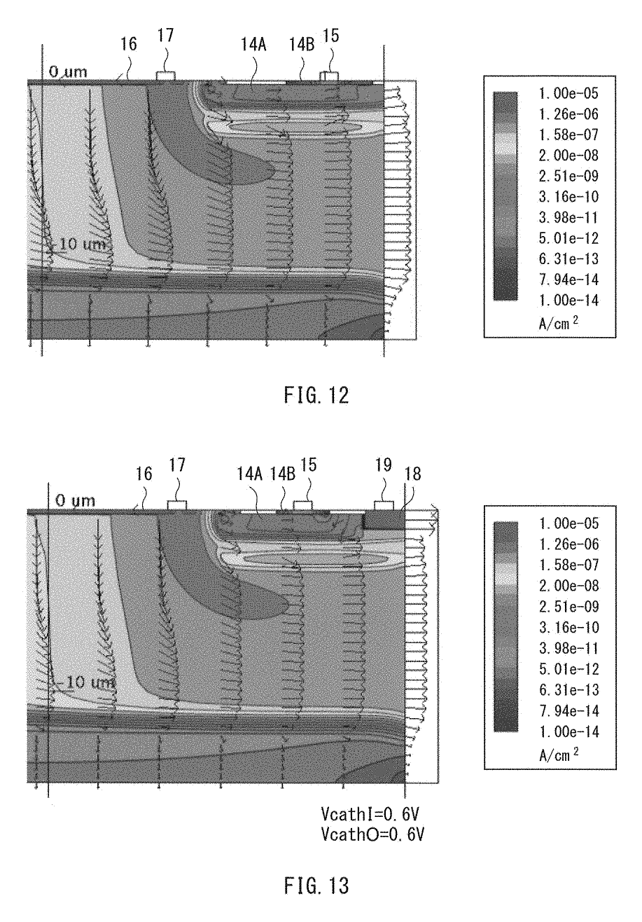

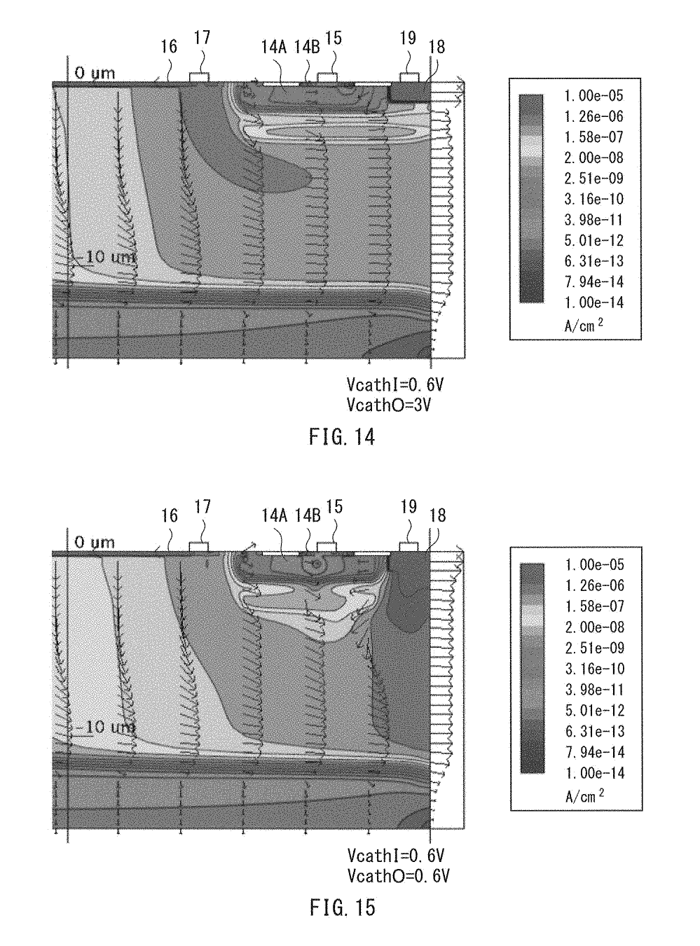

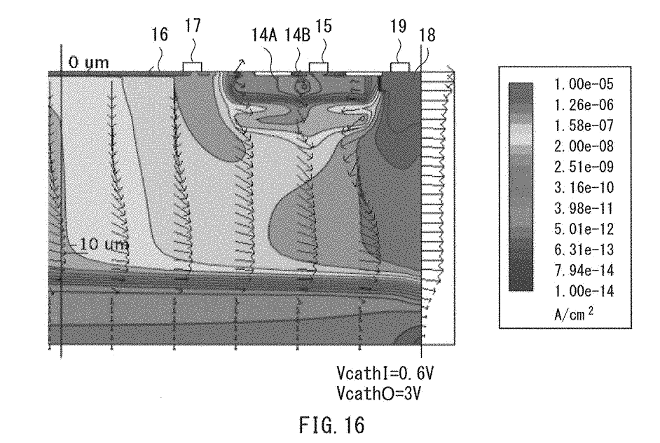

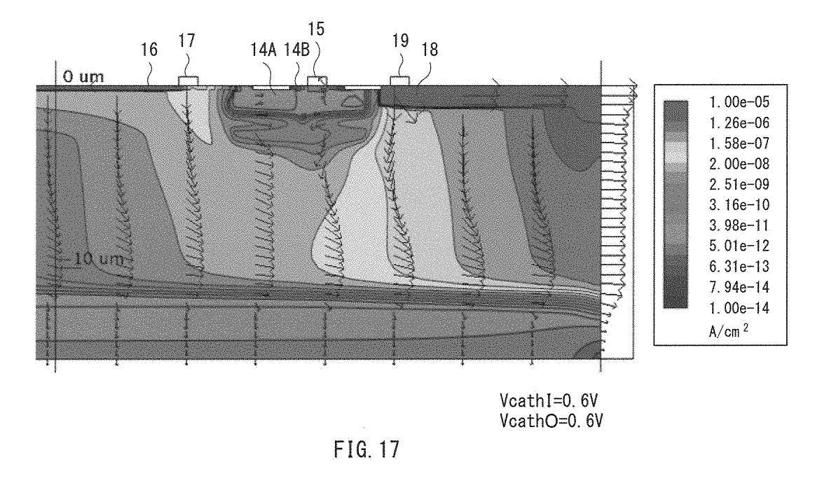

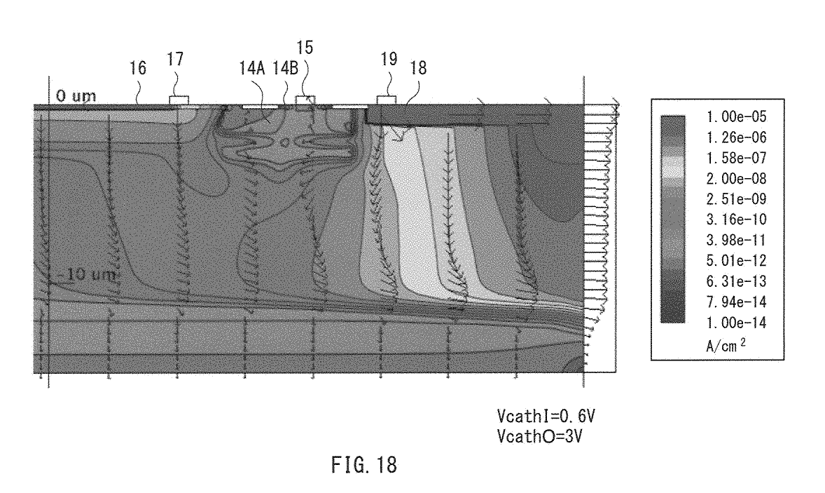

FIG. 12 illustrates an example of a simulation result in the light receiving element 200B illustrated in FIG. 10. Each of FIG. 13 and FIG. 14 illustrates an example of a simulation result in the light receiving element 100B illustrated in FIG. 9. FIG. 13 illustrates a result obtained when both of the inner cathode voltage VcathI and the outer cathode voltage VcathO are set to 0.6 V, and the anode voltage is set to a ground. FIG. 14 illustrates a result obtained when the inner cathode voltage VcathI is set to 0.6 V; the outer cathode voltage VcathO is set to 3 V; and the anode voltage is set to a ground. Each of FIG. 15 and FIG. 16 illustrates an example of a simulation result in the light receiving element 10B illustrated in FIG. 4. FIG. 15 illustrates a result obtained when both of the inner cathode voltage VcathI and the outer cathode voltage VcathO are set to 0.6 V, and the anode voltage is set to a ground. FIG. 16 illustrates a result obtained when the inner cathode voltage VcathI is set to 0.6 V; the outer cathode voltage VcathO is set to 3 V; and the anode voltage is set to a ground. Each of FIG. 17 and FIG. 18 illustrates an example of a simulation result in the light receiving element 10B illustrated in FIG. 7. FIG. 17 illustrates a result obtained when both of the inner cathode voltage VcathI and the outer cathode voltage VcathO are set to 0.6 V, and the anode voltage is set to a ground. FIG. 18 illustrates a result obtained when the inner cathode voltage VcathI is set to 0.6 V: the outer cathode voltage VcathO is set to 3 V: and the anode voltage is set to a ground.

Arrows in FIG. 12 to FIG. 18 denote directions and magnitudes of the dark current. Further, contour lines in FIG. 12 to FIG. 18 denote densities of carriers (electrons).

It is seen from FIG. 12, FIG. 13, and FIG. 14 that when the n-type region 18 is covered with the p-type well 140A, carriers (electrons) arising from the end surface 10G flow from the outer region 10D into the inner region 10C as with the case where the dark current induction section 10F is absent. It is found from FIG. 15 how carriers (electrons) arising from the end surface 10G are drawn into the dark current induction section 10F by setting the outer cathode voltage VcathO to 0.6 V. It is found from FIG. 16 that carriers (electrons) arising from the end surface 10G are dominantly pulled into the dark current induction section 10F by setting the outer cathode voltage VcathO to 3 V. It is seen from FIG. 17 and FIG. 18 how carriers (electrons) arising from the end surface 10G are dominantly drawn into the dark current induction section 10F by setting the outer cathode voltage VcathO to either 0.6 V or 3 V.

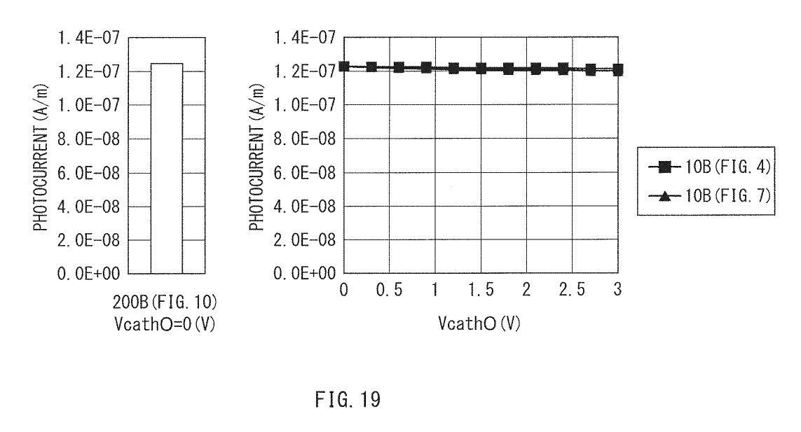

FIG. 19 illustrates an example of dependency of a photocurrent on an outer cathode voltage that is derived by the simulation. A left-hand graph in FIG. 19 illustrates an example of a magnitude of a photocurrent arising in the light receiving element 200B. A right-hand graph in FIG. 19 illustrates an example of a magnitude of a photocurrent arising in the light receiving element 10B illustrated in FIG. 4 and FIG. 7. It is seen from FIG. 19 that an influence of the presence of the dark current induction section 10F on the photocurrent is negligibly small.

[Effects]

Next, a description will be provided on effects of the radiation detector 1. The radiation detector 1 includes the dark current induction section 10F in the ring-like outer region 10D surrounding the inner region 10C in a space between the inner region 10C and the end surface 10G. The dark current induction section 10F allows carriers arising on the end surface 10G to be induced to the outside. This ensures that a dark current arising on the end surface 10G is drawn to the outside by the dark current induction section 10F, which makes it possible to reduce an influence that the dark current arising on the end surface 10G exerts on the inner region 10C even if the inner region 10C is provided in the vicinity of the end surface 10G. Further, the dark current induction section 10F may only serve as a current path for the dark current arising on the end surface 10G in the p-type semiconductor layer 12, which eliminates necessity for providing the dark current induction section 10F in large size, and eliminates necessity for providing a coating layer on the end surface 10G, or providing an impurity layer that runs through the p-type semiconductor layer 12. Therefore, it is possible to reduce an influence that the dark current arising on the end surface 10G exerts on the photocurrent, while suppressing deterioration in the S/N ratio of the photocurrent and an increase in the manufacturing costs.

### 2. Modification Examples of First Embodiment

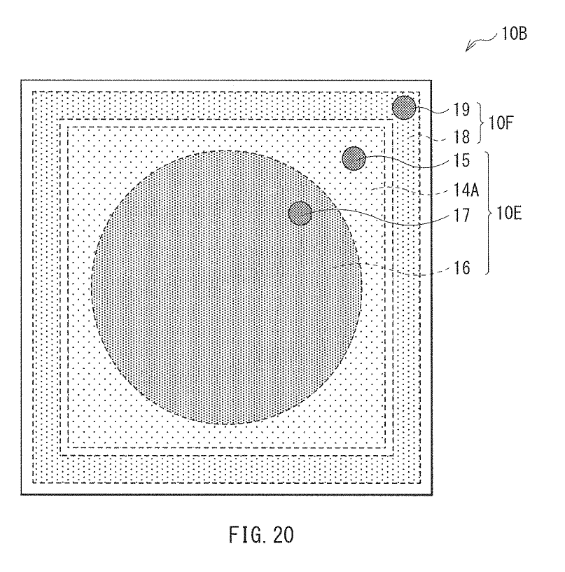

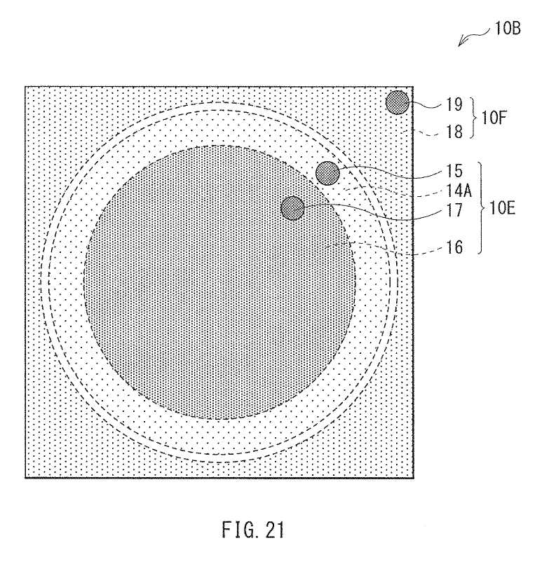

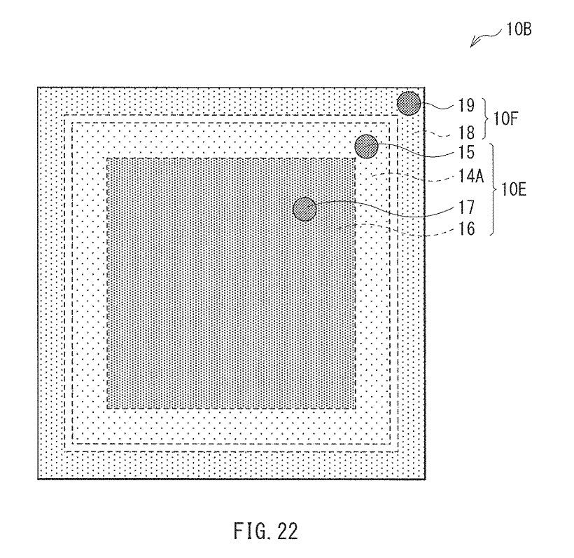

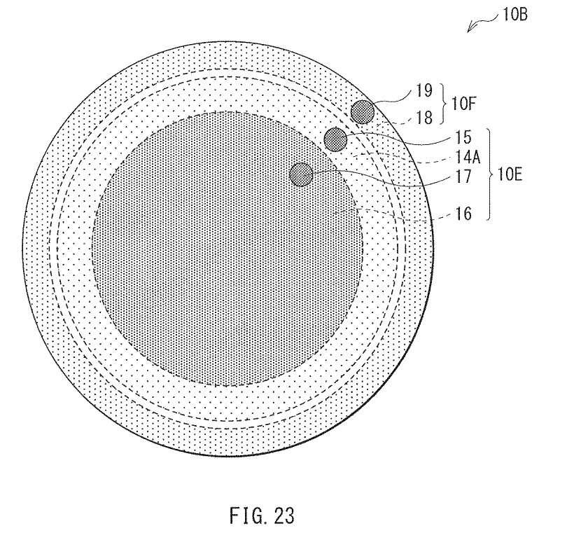

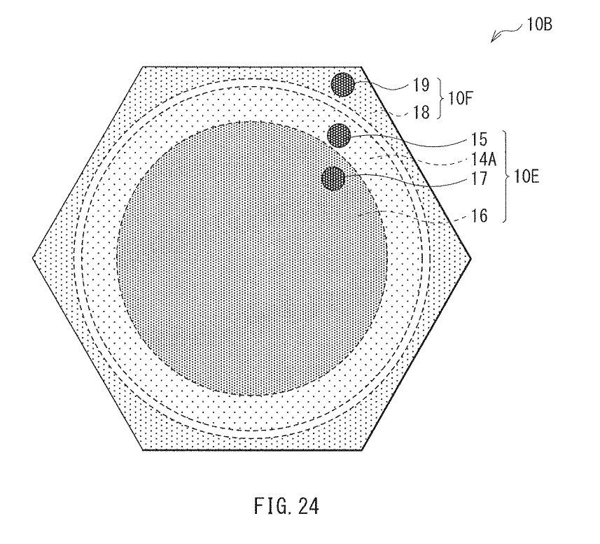

In the above-described embodiment, the n-type region 18 is disposed to be in contact with the end surface 10G: however, the n-type region 18 may be disposed on the end surface 10G with a predetermined space in between, as illustrated in FIG. 20, for example. Further, in the above-described embodiment, a width of the p-type well 14A is different depending on locations: however, for example, as illustrated in FIG. 21, the width may be constant regardless of locations. Moreover, in the above-described embodiment, the n-type region 16 takes a circular shape; however, for example, as illustrated in FIG. 22, the n-type region 16 may take a rectangular shape. Additionally, in the present modification example, when the width of the p-type well 14A is constant regardless of locations as illustrated in FIG. 21, the width of the n-type region 18 may be also constant regardless of locations as illustrated in FIG. 23, for example. At this time, as illustrated in an example in FIG. 23, the light receiving element 10B may take a cylindrical shape. Further, in the present modification example, when the width of the p-type well 14A is constant regardless of locations as illustrated in FIG. 21, the width of the n-type region 18 may be different depending on locations as illustrated in FIG. 24, for example. At this time, the light receiving element 10B may take a polygonal column shape as illustrated in an example in FIG. 24, for example.

### 3. Second Embodiment

### [Configuration]

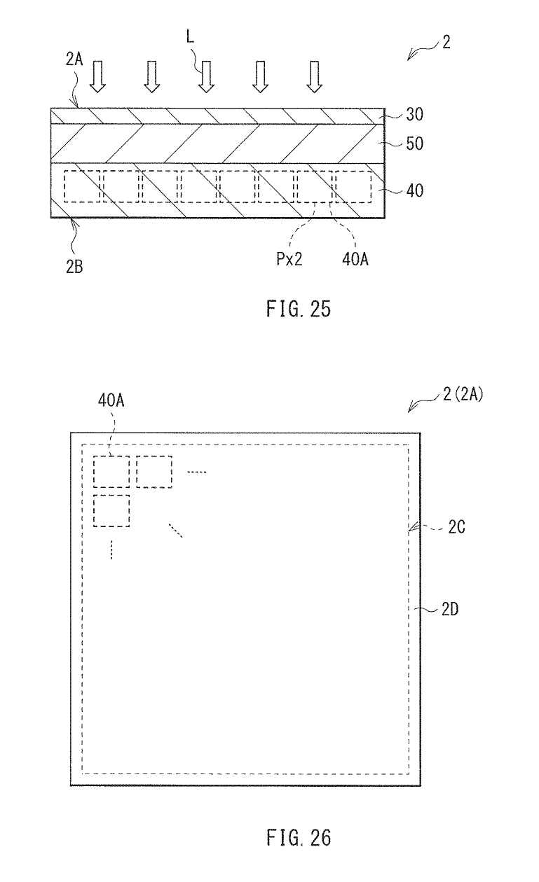

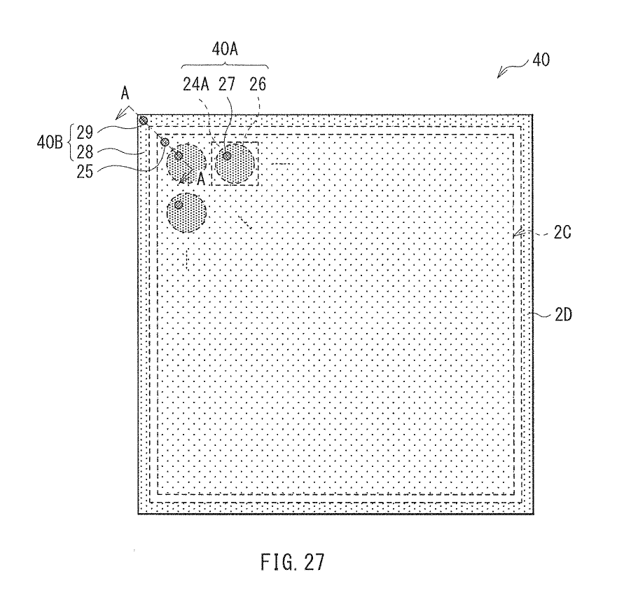

Next, a description will be provided on a radiation detector 2 according to a second embodiment of the technology. FIG. 25 illustrates an example of a cross-sectional configuration of the radiation detector 2 according to the present embodiment. FIG. 26 illustrates an example of a configuration of a top surface 2A of the radiation detector 2 illustrated in FIG. 25. The radiation detector 2 detects radiation such as α ray, β ray, γ ray, or X-ray, and is a radiation detector of an indirect conversion method. The radiation detector 2 may include, for example, a circuit substrate 40, a scintillator layer 50, and a reflective plate 30. The circuit substrate 40 corresponds to a specific example of a “functional element” in the technology. The circuit substrate 40 is disposed on bottom surface 2B side of the radiation detector 2, and the scintillator layer 50 and the reflective plate 30 are disposed on the top surface 2A side of the radiation detector 2.

The circuit substrate 40 converts an optical signal into an electrical signal. The circuit substrate 40 is configured of a plurality of photoelectric converters 40A that are formed on a top surface of a common semiconductor layer (p-type semiconductor layer 22 to be hereinafter described). The photoelectric converter 40A corresponds to a specific example of a “second functional section” in the technology. The photoelectric converter 40A generates a signal charge (photocurrent) of a charge amount corresponding to an amount of light (incident light) coming into a top surface of the photoelectric converter 40A from the scintillator layer 50 side to accumulate such a signal charge internally. The photoelectric converter 40A may be configured of, for example, a PN photodiode or a PIN photodiode.

The circuit substrate 40 has a driving circuit that drives each of the photoelectric converters 40A. The driving circuit may have, for example, a plurality of transistors that perform on/off control of the photoelectric converters 40A on the basis of a control signal from an external circuit. Each of the transistors may be configured of, for example, a field-effect thin-film transistor (TFT). The plurality of transistors are provided one by one for the photoelectric converters 40A, and a pair of the photoelectric converter 40A and the transistor configures an imaging pixel Px2. The circuit substrate 40 may include, for example, a conversion circuit that converts a photocurrent to be outputted from the photoelectric converter 40A into a voltage signal, an amplifier circuit that amplifies the voltage signal to be outputted from the conversion circuit, and an A/D conversion circuit that converts an analog signal to be outputted from the amplifier into a digital signal.

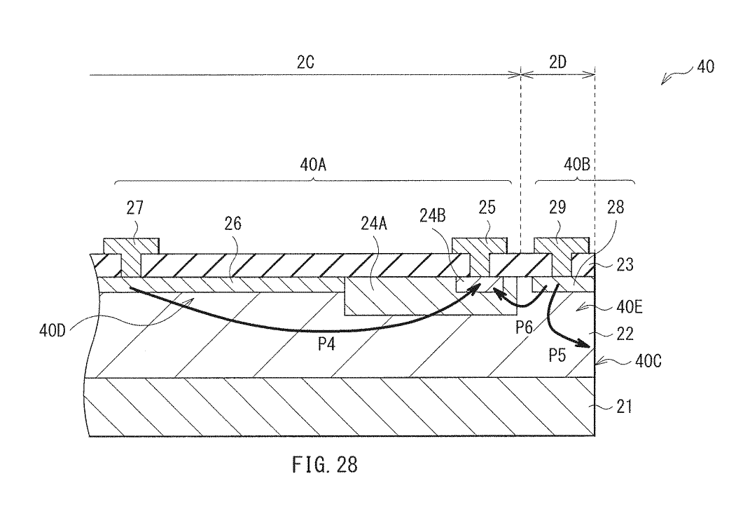

FIG. 27 illustrates an example of a bottom-surface configuration of the circuit substrate 40. FIG. 28 illustrates an example of a cross-sectional configuration of the circuit substrate 40 taken along a line A-A illustrated in FIG. 27. FIG. 28 illustrates a cross-sectional surface of the circuit substrate 40 upside down. Hereinafter, in explaining each component element inside the circuit substrate 40, an upper side of FIG. 28 is referred to as a top, and a lower side of FIG. 28 is referred to as a bottom. The circuit substrate 40 may be, for example, a chip of a millimeter or centimeter size. The circuit substrate 40 has an end surface 40C that is formed by being cut with use of dicing, dry etching, or any other method. The end surface 40C corresponds to a specific example of an “end surface” in the technology. The circuit substrate 40 may take a cuboid shape, for example. For the purpose of protecting the circuit substrate 40 or any other purpose, a protective film may be provided on the end surface 40C of the circuit substrate 40.

The circuit substrate 40 has a p-type substrate 21, and a p-type semiconductor layer 22 and an insulating layer 23 that are provided on the p-type substrate 21. The p-type semiconductor layer 22 corresponds to a specific example of a “semiconductor layer” in the technology. The p-type semiconductor layer 22 and the insulating layer 23 are configured to be stacked in this order on the p-type substrate 21. The p-type semiconductor layer 22 is exposed on the end surface 40C. In other words, the p-type semiconductor layer 22 has the end surface 40C. The p-type substrate 21 may be, for example, a bulk silicon crystal substrate containing a p-type impurity with a high concentration of about 1×10¹⁷ cm⁻³. The p-type semiconductor layer 22 may be, for example, a p-type epitaxial silicon layer with a low concentration of about 1×10¹⁵ cm⁻³. Examples of the p-type impurity may include boron (B). The insulating layer 23 is formed by thermally oxidizing a surface of the bulk silicon crystal substrate.

The circuit substrate 40 has, on the top surface of the p-type semiconductor layer 22, a pixel region 2C, and a ring-like frame region 2D surrounding the pixel region 2C in a space between the pixel region 2C and the end surface 40C. The pixel region 2C corresponds to a specific example of a “first region” in the technology. The frame region 2D corresponds to a specific example of a “second region” in the technology. The plurality of photoelectric converters 40A are disposed in the pixel region 2C on the top surface of the p-type semiconductor layer 22.

Each of the photoelectric converters 40A has a p-type well 24A in the pixel region 2C, and has a p-type region 24B on a portion of the top surface of the p-type well 24A. The p-type region 24B corresponds to a specific example of a “third semiconductor region” in the technology. The p-type region 24B is intended to lower a contact resistance between an anode electrode 25 to be later described and the p-type well 24A, and has higher p-type impurity concentration than p-type impurity concentration of the p-type semiconductor layer 22 and the p-type well 24A. The p-type well 24A is provided on an outer edge of the pixel region 2C in a circular pattern. The p-type well 24A is formed by diffusing the p-type impurity with respect to the p-type semiconductor layer 22 from the top surface of the p-type semiconductor layer 22. The p-type region 24B is formed by diffusing the p-type impurity in high concentration with respect to the p-type well 24A from the top surface of the p-type well 24A.

Each of the photoelectric converters 40A has a conductive n-type region 26 that is different from the p-type semiconductor layer 22 in a region surrounded by the p-type well 24A on the top surface of the pixel region 2C. The n-type region 26 corresponds to a specific example of a “second semiconductor region” in the technology. An outer edge of the n-type region 26 may be in contact with an inner edge of the p-type well 24A, for example. The n-type region 26 may be configured of, for example, a semiconductor with an n-type impurity concentration of about 1×10¹⁹ cm⁻³. Examples of the n-type impurity may include antimony (Sb) and arsenic (As). The n-type region 26 is formed by diffusing the n-type impurity in high concentration with respect to the p-type semiconductor layer 22 from the top surface of the p-type semiconductor layer 22. A p-n junction (junction region 40D) is provided at a boundary between the n-type region 26 and the p-type semiconductor layer 22 and at a boundary between the n-type region 26 and the p-type well 24A. The p-n junction (junction region 40D) corresponds to a specific example of a “p-n junction in second functional section” in the technology. Each of the photoelectric converters 40A has an inner cathode electrode 27 that is electrically coupled to the n-type region 26 via an opening of the insulating layer 23. The inner cathode electrode 27 corresponds to a specific example of a “second electrode” in the technology. The inner cathode electrode 27 may be made of, for example, a metallic material such as AlCu.

The circuit substrate 40 has a single or a plurality of anode electrodes 25 that are electrically coupled to the p-type region 24B via another opening of the insulating layer 23. The anode electrode 25 corresponds to a specific example of a “third electrode” in the technology. When the circuit substrate 40 has a single anode electrode 25, the single anode electrode 25 is shared by the photoelectric converters 40A. When the circuit substrate 40 has the plurality of anode electrodes 25, the plurality of anode electrodes 25 may be assigned one by one to the photoelectric converters 40A, for example. The anode electrode 25 may be made of, for example, a metallic material such as AlCu. Each of the photoelectric converters 40A serves as a current path P4 in the pixel region 2C, and controls movement of carriers in the pixel region 2C. It is to be noted that a direction of an arrow of the current path P4 indicates a current flow direction in FIG. 28. In FIG. 28, directions of arrows of current paths P5 and P6 also indicate current flow directions.

Further, the circuit substrate 40 has a conductive n-type region 28 that is different from the p-type semiconductor layer 22 in the frame region 2D. The n-type region 28 corresponds to a specific example of a “first semiconductor region” in the technology. The n-type region 28, the p-type region 24B, and the n-type region 26 are disposed in this order from the end surface 40C side. The n-type region 28 is not directly in contact with the p-type well 24A, and the n-type region 28 and the p-type well 24A are disposed with a predetermined space in between. The n-type region 28 is provided to be in contact with the end surface 40C. The n-type region 28 may be configured of, for example, a semiconductor with an n-type impurity concentration in the range of about 1×10¹⁸ cm⁻³ to about 1×10¹⁹ cm⁻³. The n-type region 28 is formed by diffusing the n-type impurity in high concentration with respect to the p-type semiconductor layer 22 from the top surface of the p-type semiconductor layer 22. A p-n junction (junction region 40E) is provided at a boundary between the n-type region 28 and the p-type semiconductor layer 22. The p-n junction (junction region 40E) corresponds to a specific example of a “p-n junction of the first functional section” in the technology. The circuit substrate 40 has an outer cathode electrode 29 that is electrically coupled to the n-type region 28 via the opening of the insulating layer 23. The outer cathode electrode 29 corresponds to a specific example of a “first electrode” in the technology. The outer cathode electrode 29 may be made of, for example, a metallic material such as AlCu. A dark current induction section 40B that makes it possible to induce carriers arising on the end surface 40C to the outside is configured of the n-type region 28, a portion directly below the n-type region 28 of the junction region 40E, and the outer cathode electrode 29. The dark current induction section 40B corresponds to a specific example of a “first functional section” in the technology. The dark current induction section 40B serves as the current path P5 in the frame region 2D.

As described above, the end surface 40C is formed by being cut with use of dicing, dry etching, or any other method. Therefore, collapse in crystal structure may exist in any way on the end surface 40C, and carriers (that is, dark current) are likely to occur due to such collapse in the crystal structure. The dark current induction section 40B makes it possible to draw and induce carriers arising on the end surface 40C to the outside by applying a predetermined voltage to the outer cathode electrode 29. Here, the “predetermined voltage” refers to a voltage that enables promotion of induction of carriers arising on the end surface 40C to the outside. For example, when a ground voltage or a negative voltage is applied to the anode electrode 25, the “predetermined voltage” refers to a positive voltage.

It is to be noted that the current path P6 may be provided also in a portion between the n-type region 28 and the p-type well 24A in the junction region 40E. However, as with the case of the first embodiment, an influence of a current flowing through the current path P6 on the current path P4 is negligibly small. Therefore, an influence of the dark current induction section 40B on the photoelectric converter 40A is negligibly small.

It is to be noted that an end of the p-type well 24A may be directly in contact with an end of the n-type region 28. Further, the end of the p-type well 24A may be also directly in contact with a portion on a lower surface of the n-type region 28 in addition to the end of the n-type region 28. Alternatively, the n-type region 28 may be provided over a wide range. At this time, from the viewpoint of an S/N ratio, it may be preferable to widen the area of the n-type region 28 without changing the area of the n-type region 26.

(Scintillator Layer 50)

The scintillator layer 50 performs wavelength conversion of radiation L incoming into the top surface 2A into a sensitivity region of the photoelectric converter 40A, and specifically converts the radiation L incoming into the top surface 2A into light. The scintillator layer 50 is configured of a phosphor that converts radiation such as α ray, β ray, γ ray, or X-ray into visible light. Examples of such a phosphor may include the materials mentioned in the above-described first embodiment. The scintillator layer 50 is disposed on the upper side of the photoelectric converter 40A as illustrated in FIG. 25. For example, the scintillator layer 50 may be formed with use of the top surface of the circuit substrate 40 as a crystal growing surface, and may be formed by performing film formation utilizing, for example, a vacuum evaporation technique.

[Manufacturing Method]

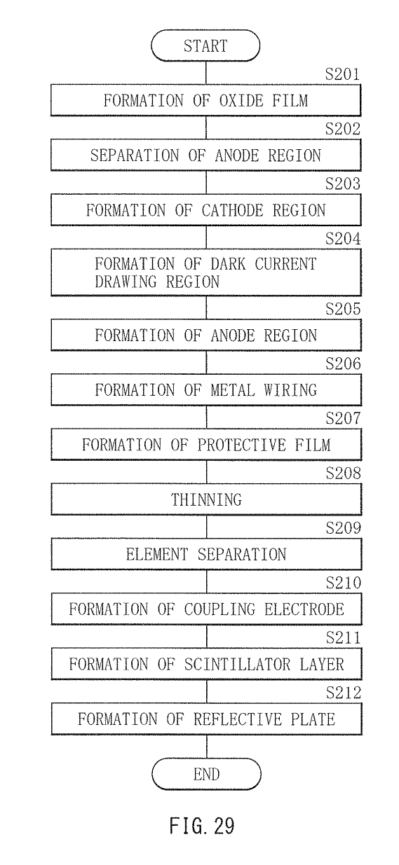

Next, a description will be provided on an example of a method of manufacturing the radiation detector 2. FIG. 29 represents an example of a procedure of manufacturing the radiation detector 2. First, a semiconductor substrate provided with the p-type semiconductor layer 22 is prepared on the p-type substrate 21. Next, an oxide film is formed (step S201). Specifically, the insulating layer 23 that is configured of the oxide film is formed by thermally oxidizing the surface of the p-type semiconductor layer 22. Thereafter, an anode region is separated (step S202). Specifically, the plurality of lattice-like p-type wells 24A are formed by performing p-type ion implantation. At this time, a concentration gradient may be provided for the p-type wells 24A by carrying out the p-type ion implantation a plurality of times.

Next, a cathode region is formed (step S203). Specifically, the n-type region 26 is formed in each region surrounded by the p-type well 24A by performing n-type ion implantation. Thereafter, a dark current drawing region is formed (step S204). Specifically, the lattice-like n-type region 28 that surrounds each of the p-type wells 24A is formed by carrying out the n-type ion implantation. At this time, when n-type impurity concentrations of the n-type regions 26 and 28 are made equal to each other, it is possible to form the n-type region 26 and the n-type region 28 collectively. Thereafter, the anode region is formed (step S205). Specifically, the single or the plurality of p-type regions 14B are formed for each of the p-type wells 24A by performing the p-type ion implantation on a portion of the top surface of each of the p-type wells 24A.

Next, metal wiring is formed (step S206). Specifically, the plurality of anode electrodes 25, the plurality of inner cathode electrodes 27, and the plurality of outer cathode electrodes 29 are formed on the insulating layer 23. At this time, the anode electrodes 15 are assigned one by one to the p-type regions 24B: the inner cathode electrodes 27 are assigned one by one to the n-type regions 26; and the outer cathode electrodes 29 are assigned one by one to the p-type wells 24A. In such a manner, the plurality of photoelectric converters 40A, and the lattice-like dark current induction section 40B that surrounds the plurality of photoelectric converters 40A for the common p-type wells 24A are formed on the top surface of the p-type semiconductor layer 22. Thereafter, a protective film (not illustrated) that is made of a material such as SiO₂ or SiN is formed over the whole top surface as necessary (step S207).

Next, when the circuit substrate 40 is used as a backside illumination type, the p-type substrate 21 is thinned (step S208). Thereafter, element separation is performed (step S209). Specifically, for example, after bonding a support substrate to the semiconductor substrate, dicing, dry etching, or any other method may be performed on a location where the dark current induction section 40B is formed on the semiconductor substrate to separate the semiconductor substrate for each of the plurality of photoelectric converters 40A sharing the p-type wells 24A. At this time, from the viewpoint of reducing dark current arising from the end surface 40C to be formed by separation, it may be preferable to carry out the element separation with use of dry etching. In such a manner, the plurality of circuit substrates 40 are formed. Thereafter, a coupling electrode (not illustrated) for coupling of each of the circuit substrates 40 to the external circuit is formed on each of the circuit substrates 40, as necessary (step S210). In such a manner, the circuit substrate 40 is manufactured.

Next, the scintillator layer 50 is formed with use of the top surface of the circuit substrate 40 as a crystal growing surface by performing film formation utilizing, for example, a vacuum evaporation technique (step S211). Finally, the reflective plate 30 is formed on the scintillator layer 50 (step S212). With use of such a procedure, the radiation detector 2 is manufactured.

[Operation]

Next, a description will be provided on an example of operation of the radiation detector 2. When the radiation L comes into the top surface 2A of the radiation detector 2, the radiation L is converted into light on the scintillator layer 50. A reverse bias voltage is applied to the photoelectric converter 40A via the driving circuit and wiring inside the circuit substrate 40. When the converted light comes into the top surface of the photoelectric converter 40A, the photoelectric converter 40A generates a signal charge (photocurrent) of an amount corresponding to (proportional to) the amount of the incident light. The signal charge (photocurrent) that is generated in the photoelectric converter 40A is drawn by the driving circuit and wiring inside the circuit substrate 40 via the current path P4.

Meanwhile, on the end surface 40C of the circuit substrate 40, carriers may occur due to collapse in the crystal structure on the end surface 40C irrespective of the presence or absence of light incidence. A reverse bias voltage is applied to the dark current induction section 40B via the driving circuit and wiring inside the circuit substrate 40. The reverse bias voltage may be applied to the dark current induction section 40B at all times or intermittently. The carriers arising on the end surface 40C are drawn by the driving circuit and wiring inside the circuit substrate 40 via the current path P5.

[Effects]

Next, a description will be provided on effects of the radiation detector 2. The radiation detector 2 includes the dark current induction section 40B in the ring-like frame region 2D surrounding the pixel region 2C in a space between the pixel region 2C and the end surface 40C. The dark current induction section 40B allows carriers arising on the end surface 40C to be induced to the outside. This ensures that a dark current arising on the end surface 40C is drawn to the outside by the dark current induction section 40B, which makes it possible to reduce an influence that the dark current arising on the end surface 40C exerts on the pixel region 2C even if the pixel region 2C is provided in the vicinity of the end surface 40C. Further, the dark current induction section 40B may only serve as a current path for the dark current arising on the end surface 40C in the p-type semiconductor layer 22, which eliminates necessity for providing the dark current induction section 40B in large size, and eliminates necessity for providing a coating layer on the end surface 40C, or providing an impurity layer that runs through the p-type semiconductor layer 22. Therefore, it is possible to reduce an influence that the dark current arising on the end surface 40C exerts on the photocurrent, while suppressing deterioration in the S/N ratio of the photocurrent and an increase in the manufacturing costs.

### 4. Modification Example Common to Each of Embodiments

In each of the above-described embodiments, the scintillator layers 20 and 50 are disposed on the top surfaces of the circuit substrates 10 and 40 respectively; however, the scintillator layers 20 and 50 may be omitted. In this case, however, each of the photoelectric converters 10E and 40A that are respectively included in the circuit substrates 10 and 40 adopts a direct conversion method that directly converts the radiation L into an electrical signal. In the present modification example, each of the photoelectric converters 10E and 40A may be configured of, for example, a semiconductor crystal such as cadmium telluride (CdTe).

In the present modification example, the scintillator layers 20 and 50 are omitted, and each of the photoelectric converters 10E and 40A adopts the direct conversion method that directly converts the radiation L into an electrical signal, which allows for higher resolution in comparison with a case where each of the photoelectric converters 10E and 40A adopts an indirect conversion method.

### 5. Third Embodiment

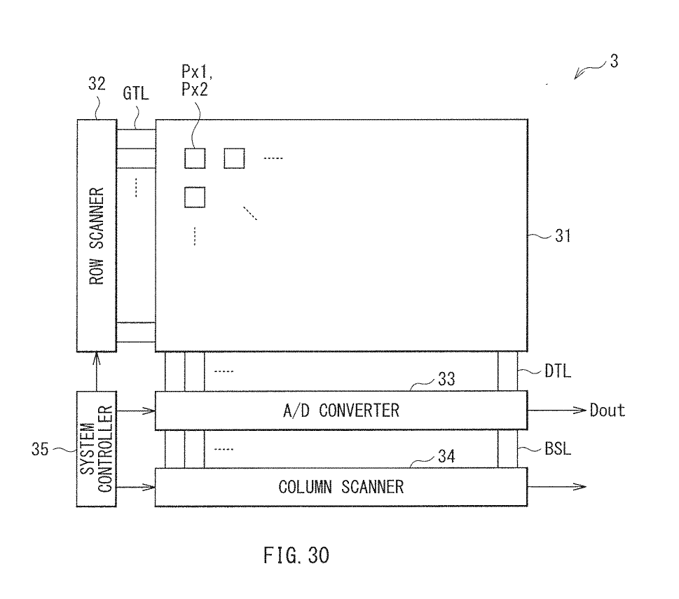

Next, a description will be provided on an imaging device 3 according to a third embodiment. FIG. 30 illustrates an example of a simplified configuration of the imaging device 3. The imaging device 3 uses any of the above-described radiation detectors 1 and 2 for an imaging section 31 to be hereinafter described, and is suitably utilized as an imaging device for medical use and any other non-destructive inspection use such as baggage checks. For example, the imaging device 3 may include the imaging section 31 on a substrate, and may include a controller that controls the imaging section 31 in a peripheral region of the imaging section 31. The controller may have, for example, a row scanner 32, an A/D converter 33, a column scanner 34, and a system controller 35. The controller corresponds to a specific example of a “controller” in the technology.

The imaging section 31 serves as an imaging region in the imaging device 3. The imaging section 31 is configured of the radiation detector 1 or the radiation detector 2. The imaging section 31 has a plurality of imaging pixels Px1 (or a plurality of imaging pixels Px2) that are disposed in a matrix pattern.

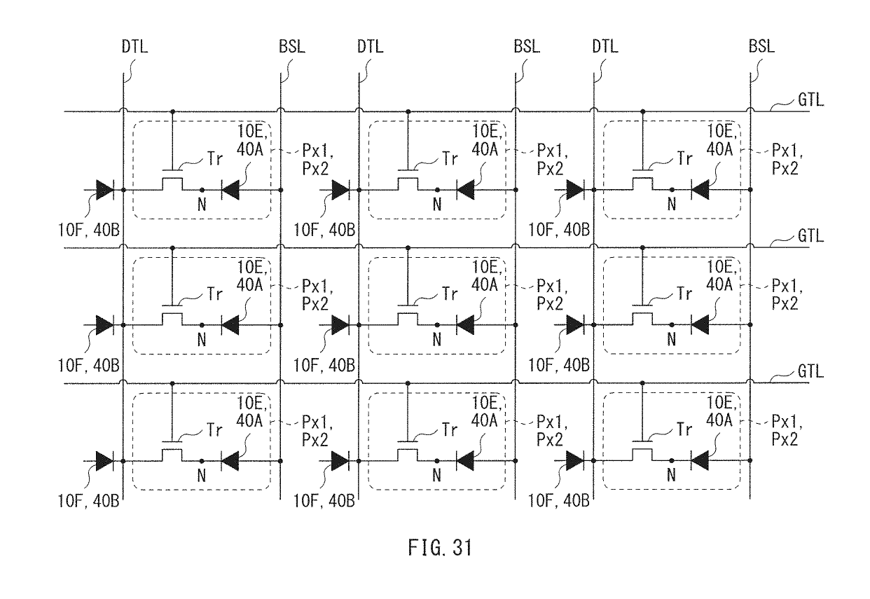

FIG. 31 illustrates an example of a circuit configuration of the imaging section 31. The imaging section 31 includes the plurality of imaging pixels Px1 (or the plurality of imaging pixels Px2) that are disposed in a matrix pattern, and further includes the dark current induction section 10F (or the dark current induction section 40B) on each of the imaging pixels Px1 (or the imaging pixels Px2).

The imaging pixel Px1 (or the imaging pixel Px2) outputs an electrical signal to be used for generation of a captured image. The imaging pixel Px1 (or the imaging pixel Px2) includes the photoelectric converter 10E (or the photoelectric converter 40A), and a transistor Tr that is electrically coupled to a node N of the photoelectric converter 10E (or the photoelectric converter 40A). The transistor Tr turns on depending on a control signal to be inputted to a gate thereof, thereby outputting a signal charge that is generated by the photoelectric converter 10E (or the photoelectric converter 40A) to signal lines DTL (to be hereinafter described). The transistor Tr may be configured of, for example, a field-effect thin-film transistor (TFT).

Further, the imaging section 31 has a plurality of signal lines DTL, and a plurality of gate lines GTL that intersect with (for example, are orthogonal to) each of the signal lines DTL. Moreover, the imaging section 31 has a plurality of bias lines BSL extending in a direction almost parallel to each of the signal lines DTL. For example, each of the plurality of imaging pixels Px1 (or the plurality of imaging pixels Px2) may be disposed at a location where each of the signal lines DTL and each of the gate lines GTL intersect with each other.

The signal line DTL is wiring for reading of a signal charge from the photoelectric converter 10E (or the photoelectric converter 40A). The gate line GTL is wiring for inputting of a control signal for on/off control of the transistor Tr to the gate of the transistor Tr. The bias line BSL is wiring for determination of an anode potential of the photoelectric converter 10E (or the photoelectric converter 40A). The gate of the transistor Tr is coupled to the gate line GTL; a source or a drain of the transistor Tr is coupled to the node N of the photoelectric converter 10E (or the photoelectric converter 40A): and an electrode uncoupled to the node N of the source and the drain of the transistor Tr is coupled to the signal line DTL. The node N of the photoelectric converter 10E (or the photoelectric converter 40A) is coupled to the source or the drain of the transistor Tr, and an anode of the photoelectric converter 10E (or the photoelectric converter 40A) is coupled to the bias line BSL. A cathode of the dark current induction section 10F (or the dark current induction section 40B) is coupled to the signal line DTL. It is to be noted that when a voltage different from a voltage to be applied to the signal line DTL is to be applied to the cathode of the dark current induction section 10F (or the dark current induction section 40B), the cathode of the dark current induction section 10F (or the dark current induction section 40B) may be preferably coupled to any wiring other than the signal line DTL.

The row scanner 32 is configured of a shift register, an address decoder, and any other elements, and may drive the imaging pixels Px1 or the imaging pixels Px2 in a row unit, for example. The signal charge to be outputted from each pixel of a pixel row that is selected and scanned by the row scanner 32 is supplied to the A/D converter 33 via each of the signal lines DTL.

The A/D converter 33 performs A/D conversion on the basis of the signal charge to be inputted via each of the signal lines DTL, and may be configured of, for example, an amplifier, a horizontal selector switch, and any other elements that are provided for each of the signal lines DTL. The A/D converter 33 controls the dark current induction section 10F (or the dark current induction section 40B) to promote induction of carriers arising on any of the end surfaces 10G and 40C to the outside. The A/D converter 33 may promote induction of carriers arising on any of the end surfaces 10G and 40C to the outside by applying a “predetermined voltage” to the cathode of the dark current induction section 10F (or the dark current induction section 40B) via each of the signal lines DTL, for example. Here, the “predetermined voltage” refers to a voltage that enables promotion of induction of carriers arising on any of the end surfaces 10G and 40C to the outside. For example, when a ground voltage or a negative voltage is applied to the anode electrodes 15 and 25, the “predetermined voltage” refers to a positive voltage.

The column scanner 34 may be configured of, for example, a shift register, an address decoder, and any other elements, and scans and sequentially drives the horizontal selector switches of the A/D converter 33. Such selective scanning by the column scanner 34 allows imaging signals Dout corresponding to signal charges to be outputted from the pixels of a pixel row that is selected by the row scanner 32 to be sequentially outputted to the outside.

A circuit section that is configured of the row scanner 32, the A/D converter 33, and the column scanner 34 may be disposed directly on a common substrate along with the imaging section 31, or may be provided on an external control IC. Alternatively, such a circuit section may be disposed on any other substrate that is coupled through a cable, for example.

The system controller 35 receives, for example, a clock delivered from the outside and data on instructions of operation modes, and outputs data such as internal information of the imaging device 3. Further, the system controller 35 has a timing generator that generates various timing signals, and performs drive control of peripheral circuits including the row scanner 32, the A/D converter 33, and the column scanner 34 on the basis of various timing signals that are generated by the timing generator.

In the present embodiment, any of the above-described radiation detectors 1 and 2 is used for the pixel section 31. This makes it possible to achieve a high-resolution and high-quality image with reduced noise.

### 6. Fourth Embodiment

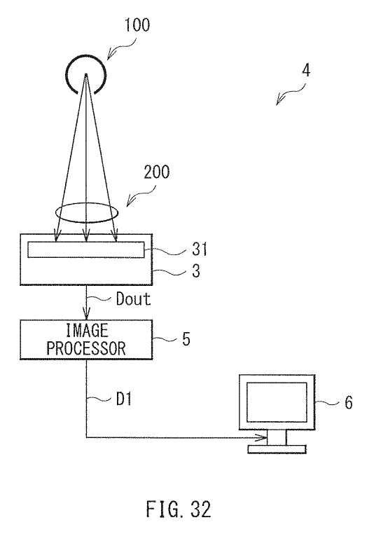

Next, a description will be provided on an imaging system 4 according to a fourth embodiment. FIG. 32 illustrates an example of a simplified configuration of the imaging system 4. The imaging system 4 includes the imaging device 3 in which any of the above-described radiation detectors 1 and 2 is used for the pixel section 31. The imaging system 4 may include, for example, the imaging device 3, an image processor 5, and a display unit 6. It is to be noted that the display unit 6 may be omitted as necessary.

The image processor 5 performs predetermined image processing on the imaging signal Dout that is obtained by the imaging device 3, and specifically generates a display signal D1 by performing the predetermined image processing on the imaging signal Dout. The display unit 6 performs image display based on the imaging signal Dout that is obtained by the imaging device 3, and specifically displays an image on the basis of the imaging signal (display signal D1) that has been already processed by the image processor 5.

In the present embodiment, a radiation component that is transmitted through an object 200 in the radiation applied toward the object 200 from a radiation source 100 is detected by the imaging device 3. The imaging signal Dout that is obtained through detection performed by the imaging device 3 is subjected to the predetermined processing by the image processor 5. The imaging signal (display signal D1) having been subjected to the predetermined processing is outputted to the display unit 6, and the image based on the display signal D1 is displayed on a monitor screen of the display unit 6.

As described above, in the present embodiment, any of the above-described radiation detectors 1 and 2 is used in the imaging device 3. This makes it possible to achieve a high-resolution and high-quality image with reduced noise.

### 7. Modification Example of Fourth Embodiment

In the above-described fourth embodiment, the imaging system 4 may further include a molding apparatus (not illustrated) that molds a solid object on the basis of the imaging signal (3D CAD (Computer-Aided Design) signal) that has been processed by the image processor 5. An example of the molding apparatus may be a 3D printer. The image processor 5 generates the 3D CAD signal by performing the predetermined image processing on the imaging signal Dout.

In the present modification example, any of the above-described radiation detectors 1 and 2 is used in the imaging device 3. This makes it possible to form a highly accurate solid object.

Although the technology is described thus far with reference to the embodiments and modification examples thereof, the technology is not limited thereto and may be modified in a variety of ways.

For example, in each of the above-described embodiments and modification examples thereof, a conductivity type of a semiconductor may be opposite to the above-described conductivity type. For example, if a conductivity type of a semiconductor is described as the p type, the p type may be replaced with the n type; and if a conductivity type of a semiconductor is described as the n type, the n type may be replaced with the p type.

Further, for example, in each of the above-described embodiments and modification examples thereof, a pin structure may be applicable instead of the p-n junction.

Moreover, for example, in each of the above-described embodiments and modification examples thereof, a section having a light-emitting function or a memory function may be used instead of the photoelectric converter 10E and the photoelectric converter 40A.

It is to be noted that the effects described in the present description are merely examples. The effects of the technology are not limited to those described in the present description. The technology may have any effects other than those described in the present description.

It is to be noted that the technology may be configured as follows.

(1)

A functional element including:

a first region and a ring-like second region on a top surface of a semiconductor layer having an end surface, the second region surrounding the first region in a space between the first region and the end surface; and

a first functional section in the second region, the first functional section allowing for induction of carriers arising on the end surface to outside.

(2)

The functional element according to (1), wherein the first functional section has a p-n junction or a pin structure.

(3)

The functional element according to (2), wherein the p-n junction or the pin structure of the first functional section is formed at a boundary between a first semiconductor region and the semiconductor layer, a conductivity type of the first semiconductor region being different from a conductivity type of the semiconductor layer.

(4)

The functional element according to (3), wherein the first functional section has a first electrode that is electrically coupled with the first semiconductor region.

(5)

The functional element according to any one of (1) to (4), further including one or more second functional sections in the first region, the one or more second functional sections that control movement of carriers in the first region.

(6)

The functional element according to (5), wherein the one or more second functional sections have a photoelectric conversion function, a light-emitting function, or a memory function.

(7)

The functional element according to (5) or (6), wherein the one or more second functional sections have a p-n junction or a pin structure.

(8)

The functional element according to (7), wherein the one or more second functional sections have a second semiconductor region of a conductivity type that is different from a conductivity type of the semiconductor layer, and

the p-n junction or the pin structure of the one or more second functional sections is formed at a boundary between the second semiconductor region and the semiconductor layer.

(9)

The functional element according to (8), further including a second electrode, a third semiconductor region, and a third electrode in the first region, the second electrode being electrically coupled to the second semiconductor region, the third semiconductor region having higher impurity concentration of a conductivity type identical to the conductivity type of the semiconductor layer than impurity concentration of the semiconductor layer, and the third electrode being electrically coupled to the third semiconductor region.

(10)

The functional element according to (9), wherein the first semiconductor region, the third semiconductor region, and the second semiconductor region are disposed in this order from the end surface side.

(11)

An electronic apparatus provided with a functional element and a controller that controls the functional element, the functional element including:

a first region and a ring-like second region on a top surface of a semiconductor layer having an end surface, the second region surrounding the first region in a space between the first region and the end surface; and

a first functional section in the second region, the first functional section allowing for induction of carriers arising on the end surface to outside.

(12)

The electronic apparatus according to (11), wherein the controller controls the first functional section to promote induction of carriers arising on the end surface to outside.

This application claims the priority on the basis of Japanese Patent Application No. 2014-160216 filed on Aug. 6, 2014 in Japan Patent Office, the entire contents of which are incorporated in this application by reference.

Those skilled in the art could assume various modifications, combinations, subcombinations, and changes in accordance with design requirements and other contributing factors. However, it is understood that they are included within a scope of the attached claims or the equivalents thereof.

What is claimed is:

1. A functional element comprising:
a first region and a ring-like second region on a top surface of a semiconductor layer having an end surface, the second region surrounding the first region in a space between the first region and the end surface; and
a first functional section in the second region, the first functional section allowing for induction of carriers arising on the end surface to outside.

2. The functional element according to claim 1, wherein the first functional section has a p-n junction or a pin structure.

3. The functional element according to claim 2, wherein the p-n junction or the pin structure of the first functional section is formed at a boundary between a first semiconductor region and the semiconductor layer, a conductivity type of the first semiconductor region being different from a conductivity type of the semiconductor layer.

4. The functional element according to claim 3, wherein the first functional section has a first electrode that is electrically coupled with the first semiconductor region.

5. The functional element according to claim 4, further comprising one or more second functional sections in the first region, the one or more second functional sections that control movement of carriers in the first region.

6. The functional element according to claim 5, wherein the one or more second functional sections have a photoelectric conversion function, a light-emitting function, or a memory function.

7. The functional element according to claim 5, wherein the one or more second functional sections have a p-n junction or a pin structure.

8. The functional element according to claim 7, wherein the one or more second functional sections have a second semiconductor region of a conductivity type that is different from a conductivity type of the semiconductor layer, and
the p-n junction or the pin structure of the one or more second functional sections is formed at a boundary between the second semiconductor region and the semiconductor layer.

9. The functional element according to claim 8, further comprising a second electrode, a third semiconductor region, and a third electrode in the first region, the second electrode being electrically coupled to the second semiconductor region, the third semiconductor region having higher impurity concentration of a conductivity type identical to the conductivity type of the semiconductor layer than impurity concentration of the semiconductor layer, and the third electrode being electrically coupled to the third semiconductor region.

10. The functional element according to claim 9, wherein the first semiconductor region, the third semiconductor region, and the second semiconductor region are disposed in this order from the end surface side.

11. An electronic apparatus provided with a functional element and a controller that controls the functional element, the functional element comprising:
a first region and a ring-like second region on a top surface of a semiconductor layer having an end surface, the second region surrounding the first region in a space between the first region and the end surface; and
a first functional section in the second region, the first functional section allowing for induction of carriers arising on the end surface to outside.

12. The electronic apparatus according to claim 11, wherein the controller controls the first functional section to promote induction of carriers arising on the end surface to outside.
